(19) United States
(12) Patent Application Publication
(10) Pub. No.: US 2022/0190087 A1
(43) Pub. Date: Jun. 16, 2022

(54) BONDING AREA CIRCUIT

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yicheng CHEN, Wuhan, Hubei (CN); Hong WEN, Wuhan, Hubei (CN)

(21) Appl. No.: 17/261,761

(22) PCT Filed: Jun. 23, 2020
(86) PCT No.: PCT/CN2020/097800

§ 371 Date: Jan. 20, 2021

(30) Foreign Application Priority Data
May 18, 2020 (CN) 202010420072.7

(51) Int. Cl. H01L 27/32

(52) U.S. Cl. CPC H01L 27/3276

(57) ABSTRACT

A bonding area circuit includes a plurality of wires. An end area of each of the wires is smaller than a front end area of each of the wires. A distance between the front end areas of two adjacent wires is larger than a distance between the end areas of the two adjacent wires. The present invention makes the distance between the end areas becomes longer. In this way, the short circuit issue during the testing or operating processes due to the residue metal scraps could be alleviated.

### FIELD OF THE INVENTION

The present invention relates to a display, and more particularly, to a bonding area circuit.

### BACKGROUND

OLED has advantages such as self-illuminating, flexible, high laminating efficiency, and short response time. However, because of the manufacturing process limitation, it's difficult to manufacture a large-size screen. As the development progress of the display technique, such as mobile equipment, cell phone, or tablet, the user has higher demands for display quality, which leads the high demands for products with high resolutions.

High resolution means that a better image quality could be provided but it also means that the bonding wires become more condensed because the pixel number increases within the same size of screen. In the conventional bonding wire design and the bonding equipment limitation, residue metal scraps may exist due to mechanical slicing or laser slicing. This may cause the adjacent wires/pins to be incorrectly connected. Therefore, in the testing or driving process after bonding process, the short circuit issue may occur. For example, after a huge panel is sliced by laser into small panels, because the residue metal scraps at the slicing edge and the distance between wires is short, the residue may connect the two adjacent wires. This introduces the short circuit issue or other issues in the testing or operating processes.

### SUMMARY

One objective of an embodiment of the present invention is to provide a bonding area circuit to solve the above-mentioned issue. The bonding area circuit could reduce the short-circuit risk between the wires through optimizing the bonding area circuit.

According to an embodiment of the present invention, a bonding area circuit is disclosed. The bonding area circuit comprises: a plurality of wires, an end area of each of the wires is smaller than a front end area of each of the wires; wherein a distance between the front end areas of two adjacent wires is larger than a distance between the end areas of the two adjacent wires; wherein the wires are manufactured by a lithography and etching process, and the end area is chamfered.

According to one embodiment of the present invention, the chamfered angle is between 30 to 170 degrees.

According to one embodiment of the present invention, the front end area is in a shape of a rectangular.

According to one embodiment of the present invention, the end area is in a shape of a trapezoid.

According to one embodiment of the present invention, the end area is in a shape of a triangle.

According to one embodiment of the present invention, the front end area is in a shape of a claw.

According to one embodiment of the present invention, the end area is in a shape of a trapezoid.

According to one embodiment of the present invention, the end area is in a shape of a triangle.

According to an embodiment of the present invention, a bonding area circuit is disclosed. The bonding area circuit comprises a plurality of wires. An end area of each of the wires is smaller than a front end area of each of the wires. A distance between the front end areas of two adjacent wires is larger than a distance between the end areas of the two adjacent wires.

According to one embodiment of the present invention, the wires are manufactured by a lithography and etching process.

According to one embodiment of the present invention, the end area is chamfered.

According to one embodiment of the present invention, the chamfered angle is between 30 to 170 degrees.

According to one embodiment of the present invention, the front end area is in a shape of a rectangular.

According to one embodiment of the present invention, the end area is in a shape of a trapezoid.

According to one embodiment of the present invention, the end area is in a shape of a triangle.

According to one embodiment of the present invention, the front end area is in a shape of a claw.

According to one embodiment of the present invention, the end area is in a shape of a trapezoid.

According to one embodiment of the present invention, the end area is in a shape of a triangle.

The present invention proposes a bonding area circuit. The present invention makes the end area of the wire smaller than the front end area by optimizing the wire shape in the bonding area circuit. In this way, the distance between the end areas becomes longer. In this way, when a huge panel is sliced into small panels, the short circuit issue during the testing or operating processes due to the residue metal scraps could be alleviated. Furthermore, the abnormal display image caused by the bonding wire deformation could be also reduced. This could meet the bonding requirement of the OLED high resolution product and reduce the short circuit risk of the driving circuit.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a diagram of a bonding area circuit according to an embodiment of the present invention.

FIG. 2 is a diagram of a bonding area circuit according to another embodiment of the present invention.

FIG. 3 is a diagram of a bonding area circuit according to another embodiment of the present invention.

FIG. 4 is a diagram of a bonding area circuit according to another embodiment of the present invention.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

It is understood that terminologies, such as “center,” “longitudinal,” “horizontal,” “length,” “width,” “thickness,” “upper,” “lower,” “before,” “after,” “left,” “right,” “vertical,” “horizontal,” “top,” “bottom,” “inner,” “outer,” “clockwise,” and “counterclockwise,” are locations and positions regarding the figures. These terms merely facilitate and simplify descriptions of the embodiments instead of indicating or implying the device or components to be arranged on specified locations, to have specific positional structures and operations. These terms shall not be construed in an ideal or excessively formal meaning unless it is clearly defined in the present specification. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

All of the terminologies containing one or more technical or scientific terminologies have the same meanings that persons skilled in the art understand ordinarily unless they are not defined otherwise. For example, “arrange,” “couple,” and “connect,” should be understood generally in the embodiments of the present disclosure. For example, “firmly connect,” “detachably connect,” and “integrally connect” are all possible. It is also possible that “mechanically connect,” “electrically connect,” and “mutually communicate” are used. It is also possible that “directly couple,” “indirectly couple via a medium,” and “two components mutually interact” are used.

All of the terminologies containing one or more technical or scientific terminologies have the same meanings that persons skilled in the art understand ordinarily unless they are not defined otherwise. For example, “upper” or “lower” of a first characteristic and a second characteristic may include a direct touch between the first and second characteristics. The first and second characteristics are not directly touched; instead, the first and second characteristics are touched via other characteristics between the first and second characteristics. Besides, the first characteristic arranged on/above/over the second characteristic implies that the first characteristic arranged right above/obliquely above or merely means that the level of the first characteristic is higher than the level of the second characteristic. The first characteristic arranged under/below/beneath the second characteristic implies that the first characteristic arranged right under/obliquely under or merely means that the level of the first characteristic is lower than the level of the second characteristic.

Different methods or examples are introduced to elaborate different structures in the embodiments of the present disclosure. To simplify the method, only specific components and devices are elaborated by the present disclosure. These embodiments are truly exemplary instead of limiting the present disclosure. Identical numbers and/or letters for reference are used repeatedly in different examples for simplification and clearance. It does not imply that the relations between the methods and/or arrangement. The methods proposed by the present disclosure provide a variety of examples with a variety of processes and materials. However, persons skilled in the art understand ordinarily that the application of other processes and/or the use of other kinds of materials are possible.

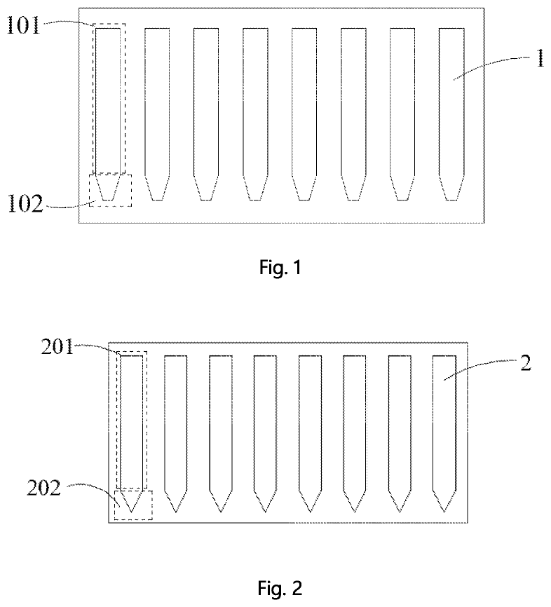

Please refer to FIG. 1. FIG. 1 is a diagram of a bonding area circuit according to an embodiment of the present invention. The bonding area circuit comprises a plurality of wires 1. The end area 102 of each of the wires 1 is smaller than the front end area 101 of each of the wires. The distance between the front end areas of two adjacent wires 1 is larger than the distance between the end areas of the two adjacent wires 1.

As shown in FIG. 1, the distance between the front end areas of two adjacent wires 1 remains the same and could be 10-15 micrometers. However, the distance between the front end areas of two adjacent wires 1 could be different. In this embodiment, all the distances between the front end areas of two adjacent wires 1 are the same but this is only an example, not a limitation of the present invention.

The wires 1 are manufactured by a lithography and etching process, and the end area 102 of the wire 1 is chamfered through the lithography and etching process. The chamfered angle is 30-170 degrees. Because the end area 102 of the wire 1 is chamfered, this increases the distance between end areas 102 and alleviates the short circuit issue caused by the metal residue on the adjacent wires due to the slicing operation.

As shown in FIG. 1, the front end area 101 of the wire 1 is in a shape of rectangular and the end area 102 of the wire 1 is in a shape of trapezoid. In this embodiment, the end area 102 of the wire 1 is in a shape of isosceles trapezoid. Similarly, this is only an example, not a limitation of the present invention. Because the end area 102 is the shape of isosceles trapezoid, the distance between the wires 1 becomes larger. When a huge panel is sliced into small panels, the residue metal scraps left on the end area 102 could effectively avoid the wires 1 without connecting adjacent wires 1. This could alleviate the short circuit issue.

Please refer to FIG. 2. FIG. 2 is a diagram of a bonding area circuit according to another embodiment of the present invention. As shown in FIG. 2, the distance between front end areas 201 of adjacent wires 2 remains the same, which is 10-15 micrometers. The wires 2 are manufactured by a lithography and etching process. The front end area 201 of the wire 2 is in a shape of rectangular and the end area 202 of the wire 2 is in a shape of triangle. As shown in FIG. 2, the end area 202 of the wire 2 is in a shape of isosceles triangle but this is only an example, not a limitation of the present invention. Similarly, because the end area 202 is the shape of isosceles triangle, the distance between the wires 2 becomes larger. When a huge panel is sliced into small panels, the residue metal scraps left on the end area 202 could effectively avoid the wires 2 without connecting adjacent wires 2. This could alleviate the short circuit issue.

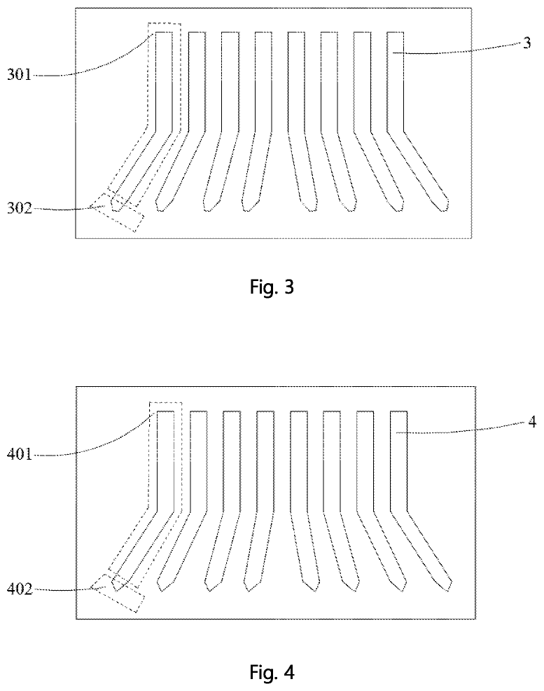

Please refer to FIG. 3. FIG. 3 is a diagram of a bonding area circuit according to another embodiment of the present invention. As shown in FIG. 3, the distances between front end areas of the adjacent wires 3 are different from one to another. The distance between front end areas of the adjacent wires 3 is 10-15 micrometers. The front end area 201 of the wire 2 is in a shape of claw and the end area 202 of the wire 2 is in a shape of trapezoid. Similarly, because the end area 302 is the shape of trapezoid, the distance between the wires 3 becomes larger. When a huge panel is sliced into small panels, the residue metal scraps left on the end area 302 could effectively avoid the wires 3 without connecting adjacent wires 3. This could alleviate the short circuit issue.

Please refer to FIG. 4. FIG. 4 is a diagram of a bonding area circuit according to another embodiment of the present invention. As shown in FIG. 4, the distance between front end areas 401 of adjacent wires 4 remains the same, which is 10-15 micrometers. The wires 4 are manufactured by a lithography and etching process. The front end area 401 of the wire 4 is in a shape of claw and the end area 402 of the wire 4 is in a shape of triangle. Similarly, because the end area 202 is the shape of triangle, the distance between the wires 4 becomes larger. When a huge panel is sliced into small panels, the residue metal scraps left on the end area 402 could effectively avoid the wires 4 without connecting adjacent wires 4. This could alleviate the short circuit issue.

Please note, the end area of the wire could be chamfered by other processes or could be manufactured into another shape to increase the distance between the end areas of the adjacent wires so that the short circuit issue caused by the metal residue could be alleviated. These changes also fall within the scope of the present invention.

The present invention proposes a bonding area circuit. The present invention makes the end area of the wire smaller than the front end area by optimizing the wire shape in the bonding area circuit. In this way, the distance between the end areas becomes longer. In this way, when a huge panel is sliced into small panels, the short circuit issue during the testing or operating processes due to the residue metal scraps could be alleviated. Furthermore, the abnormal display image caused by the bonding wire deformation could be also reduced. This could meet the bonding requirement of the OLED high resolution product and reduce the short circuit risk of the driving circuit.

Above are embodiments of the present invention, which does not limit the scope of the present invention. Any modifications, equivalent replacements or improvements within the spirit and principles of the embodiment described above should be covered by the protected scope of the invention.

What is claimed is:

1. A bonding area circuit, comprising:
a plurality of wires, an end area of each of the wires is smaller than a front end area of each of the wires;
wherein a distance between the front end areas of two adjacent wires is larger than a distance between the end areas of the two adjacent wires;
wherein the wires are manufactured by a lithography and etching process, and the end area is chamfered.

2. The bonding area circuit of claim 1, wherein the chamfered angle is between 30 to 170 degrees.

3. The bonding area circuit of claim 1, wherein the front end area is in a shape of a rectangular.

4. The bonding area circuit of claim 3, wherein the end area is in a shape of a trapezoid.

5. The bonding area circuit of claim 3, wherein the end area is in a shape of a triangle.

6. The bonding area circuit of claim 1, wherein the front end area is in a shape of a claw.

7. The bonding area circuit of claim 6, wherein the end area is in a shape of a trapezoid.

8. The bonding area circuit of claim 6, wherein the end area is in a shape of a triangle.

9. A bonding area circuit, comprising:
a plurality of wires, an end area of each of the wires is smaller than a front end area of each of the wires, wherein a distance between the front end areas of two adjacent wires is larger than a distance between the end areas of the two adjacent wires.

10. The bonding area circuit of claim 9, wherein the wires are manufactured by a lithography and etching process.

11. The bonding area circuit of claim 9, wherein the end area is chamfered.

12. The bonding area circuit of claim 11, wherein the chamfered angle is between 30 to 170 degrees.

13. The bonding area circuit of claim 9, wherein the front end area is in a shape of a rectangular.

14. The bonding area circuit of claim 13, wherein the end area is in a shape of a trapezoid.

15. The bonding area circuit of claim 13, wherein the end area is in a shape of a triangle.

16. The bonding area circuit of claim 9, wherein the front end area is in a shape of a claw.

17. The bonding area circuit of claim 16, wherein the end area is in a shape of a trapezoid.

18. The bonding area circuit of claim 16, wherein the end area is in a shape of a triangle.
